(19) United States
(12) Patent Application Publication
(10) Pub. No.: US 2008/0232169 A1
(43) Pub. Date: Sep. 25, 2008

(54) NAND-LIKE MEMORY ARRAY EMPLOYING HIGH-DENSITY NOR-LIKE MEMORY DEVICES

(75) Inventors: Massimiliano Frulio, Milano (IT); Lorenzo Bedarida, Vimercate (MI) (IT); Simone Bartoli, Cambiago (MI) (IT); Fabio Tassan Caser, Arcore (MI) (IT)

Correspondence Address: SCHWEGMAN, LUNDBERG & WOESSNER / ATMEL, P.O. BOX 2938, MINNEAPOLIS, MN, 55402, US

(73) Assignee: ATMEL CORPORATION, San Jose, CA (US)

(21) Appl. No.: 11/688,740

(22) Filed: Mar. 20, 2007

(51) Int. Cl. G11C 11/34

(52) U.S. Cl. 365/185.17

(57) ABSTRACT

A flash memory integrated circuit includes a plurality of flash memory arrays. A global word line driver is associated with each array, each global word line driver coupled to a plurality of select lines. A plurality of sense amplifiers are individually coupled to a plurality of bit lines. A plurality of sub arrays in each array each include a plurality of NAND flash memory cells coupled to local word lines and local bit lines. A local word line driver is associated with each sub-array and coupled to the plurality of select lines and configured to drive ones of the local word lines in its sub array associated with selected ones of the plurality of NAND flash memory cells in its sub-array. A local bit line driver is coupled between selected ones of the local bit lines in each sub array and selected ones of the plurality of bit lines.

### BACKGROUND OF THE INVENTION

1. Field of the Invention

The present invention relates to non-volatile memory arrays. More particularly, the present invention relates to a NAND-like memory array employing high- density NOR-like memory devices.

2. The Prior Art

Non-volatile memory devices are widely employed in the market of portable systems such as laptops, PDAs, mobile phones and others. Non-volatile memories allow storage of binary information regardless of whether or not power is applied to the device. This is a very useful feature for portable systems.

Non-volatile memories are realized using floating-gate devices that can change their physical state. Two or more physical states are obtained by changing the threshold of the floating gate device by means of injection and extraction of electrons in the floating gate. The injection of electrons will result in a higher threshold, corresponding for instance to a programmed state. The successive extraction of electrons will bring the threshold to a lower value, corresponding for instance to an erase state.

Recent applications require higher memory capacity at the lowest price, pushing the developing of new architectures and scaling down of the technologies.

In the present market there are two kinds of flash memories, intended to satisfy different requirements and applications. NAND flash memories have very high density, but poor random-access read performance. Such memories are suitable for data storage where sequential access is the major application. A very high number of read circuit blocks are used to sustain the sequential read throughput.

The architecture of traditional NAND flash memories is focused on the efficiency of the chip from the die size point of view only, accepting very poor performance for random-access read operations. NAND flash memories have a Tacc (random read access) in the range of 5-10 us, while the performance needed for code execution is on the order of 100 ns, which is the typical Tacc of NOR flash memories.

As shown in FIG. 1, conventional NAND memory arrays 10 are divided into two or more arrays of cells 12. The selection of the cell is made by means of word-lines 14 that connect to the gates of the cells, and bit-lines 16 that connect to the drains of the string selectors. The word lines are driven by a word line driver 18, while the bit lines are driven by read circuitry 20 placed at least at one end of the columns of the array. The number of the read circuits is chosen in order to sustain the throughput of the sequential access.

This prior-art approach has several disadvantages: bit lines are drawn at the same pitch of the cells (˜2F) and they are as long as the chip height, therefore the capacitance of the bit line is huge compared to the cell current and the resistivity, combined with this capacitance, results in an RC time-constant in the order of micro-seconds; word lines 250, driven by the row decoder 200, have the same pitch of the cell (2F) and, as for the bit lines, they have an RC in the order of micro-seconds. For these reasons the read access of a memory cell requires a time in the order of microseconds.

On the other hand, NOR flash memories have lower density but very high performance for the read random access; they are suitable for code execution rather then data storage. The cost per bit of the NOR flash memory devices is many times higher than the NAND flash memory devices, while the random read access is up to 100 times faster.

Many factors contribute to these different features of NAND flash memory devices and NOR flash memory devices, but the main difference is the memory cell itself. Floating gate devices of NOR flash memories have the source line and the bit line plug shared by two cells. Thus, as shown in FIG. 2, floating gate transistors 30 and 32 forming two cells have their drains coupled together and connected to bit line 34. The source of transistor 30 is coupled to source line 36 and the source of transistor 32 is coupled to source line 38. Similarly, floating gate transistors 40 and 42 forming two cells have their drains coupled together and connected to bit line 36. The source of transistor 40 is coupled to source line 38 and the source of transistor 32 is coupled to source line 44.

As shown in FIG. 3, the floating gate devices in NAND flash memories are organized into a “string,” formed from many cells (e.g., cells 50, 32, 54, and 56) connected in series and having one select transistor 58 coupled to a bit line 60 at one end of the string and one select transistor 62 on coupled to a source line 64 at the other end of the string. Recent generations of NAND memories have strings with sixteen or thirty-two cells. Source-line and bit-line connections have a dimension comparable with the floating gate device. It is well known that NAND flash cells have higher area efficiency than NOR flash cells. For a minimum geometry F that defines the technology step, a NOR memory cell typically has an area close to 10 F², while a NAND memory cell typically has an area close to 6 F² or 5 F², depending on whether the string has sixteen or thirty-two cells.

### BRIEF DESCRIPTION OF THE INVENTION

A flash memory integrated circuit includes a plurality of flash memory arrays. A global word line driver is associated with each array, each global word line driver coupled to a plurality of select lines. A plurality of sense amplifiers are individually coupled to a plurality of bit lines. A plurality of sub arrays each include a plurality of NAND flash memory cells coupled to local word lines and local bit lines. A local word line driver is associated with each sub-array and coupled to the plurality of select lines and configured to drive ones of the local word lines in its sub array associated with selected ones of the plurality of NAND flash memory cells in its sub-array. A local bit line driver is coupled between selected ones of the local bit lines in each sub array and selected ones of the plurality of bit lines.

### BRIEF DESCRIPTION OF THE DRAWING FIGURES

FIG. 1 is a block diagram showing how a typical NAND flash memory array may be organized.

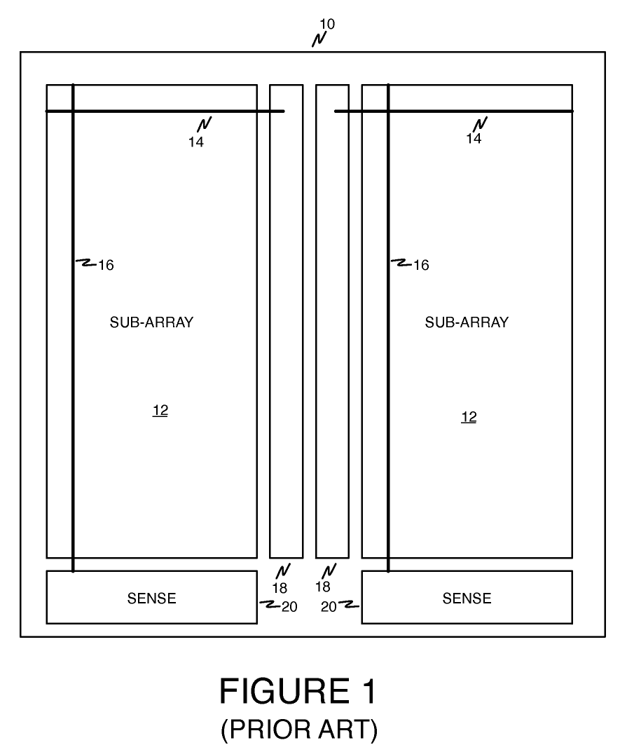

FIGS. 2 and 3 are schematic diagrams showing flash memory cells arranged is NOR and NAND configurations, respectively.

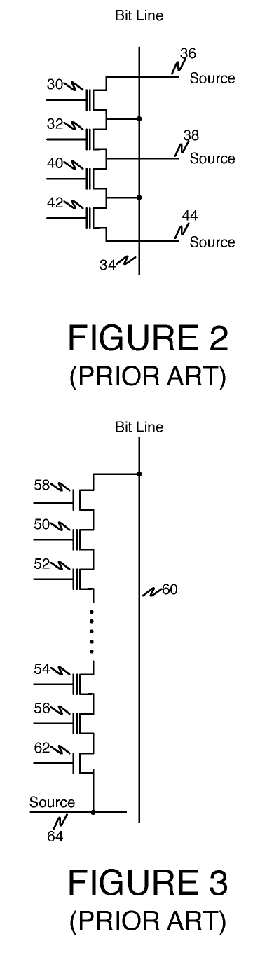

FIG. 4 is a block diagram showing how a NAND flash memory integrated circuit may be organized according to the principles of the present invention.

FIG. 5 is a block diagram showing in more detail how a NAND flash memory integrated circuit may be organized according to the principles of the present invention.

FIG. 6 is a schematic diagram showing how the word lines of a sub-array in a flash memory array may be driven with local word line drivers in accordance with the present invention.

FIG. 7 is a schematic diagram showing how a hierarchical column decoder may be used to address a NAND flash memory in accordance with the present invention.

### DETAILED DESCRIPTION OF THE INVENTION

Persons of ordinary skill in the art will realize that the following description of the present invention is illustrative only and not in any way limiting. Other embodiments of the invention will readily suggest themselves to such skilled persons.

The present invention is an architecture for flash memories that combines the advantages of the chip size of NAND flash memory architectures and the performance of NOR flash memory architectures. The flash memory architecture of the present invention ameliorates the problems of the prior-art arrays, achieving a read performance in the order of ˜100 ns with a small increase in chip area.

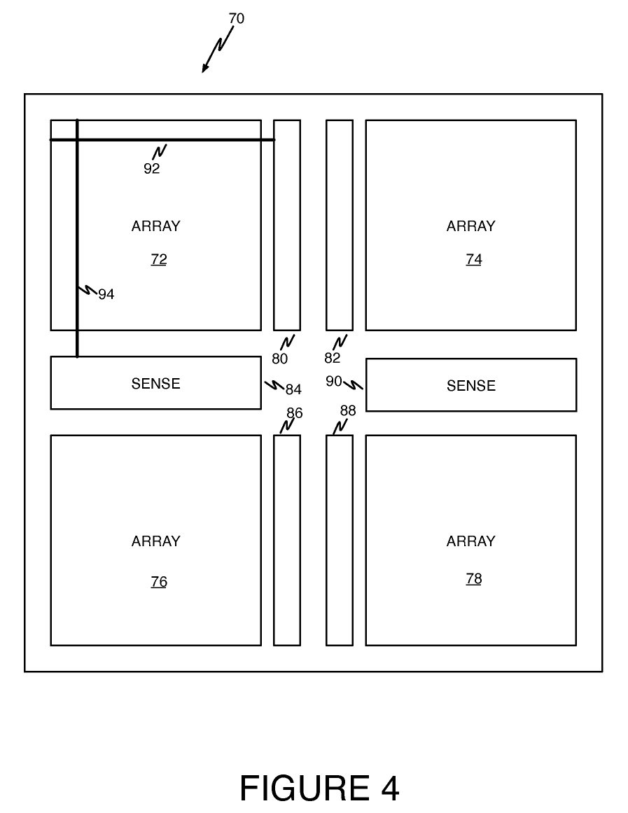

Referring now to FIG. 4, a flash memory integrated circuit 70 according to the present invention is shown. The memory integrated circuit 70 is divided in a plurality of arrays 72, 74, 76, and 78 as seen in FIG. 4. Global word line driver 80 drives word lines in array 72. Global word line driver 82 drives word lines in array 74. Sense amplifiers 84 drive bit lines in array 72 and array 76. Global word line driver 86 drives select lines in array 76. Global word line driver 88 drives select lines in array 78. Sense amplifiers 90 drive bit lines in array 74 and array 78. An exemplary word line 92 associated with array 72 is shown coupled to global word line 80 and an exemplary bit line 94 is shown coupled to sense amplifiers 84. Persons of ordinary skill in the art will readily appreciate that the number of word lines and bit lines will depend on the size (number of memory cells) of the memory integrated circuit. Such skilled persons will also understand the circuits employed to configure the word line drivers and sense amplifiers. These circuits will not be shown herein in order to avoid unnecessarily over complicating the disclosure.

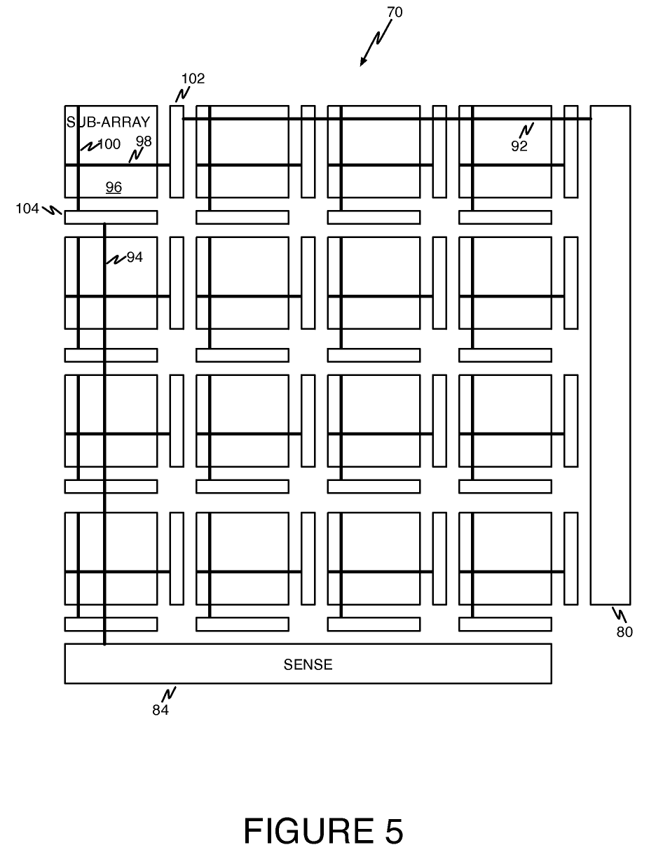

Referring now to FIG. 5, it may be seen that each array (e.g., array 72) is further divided into sub-arrays 96. Each sub-array 96 has a set of local word lines 98 and local bit lines 100. The local word lines 98 are driven by a local word line selector 102 to which exemplary local word line 98 is shown coupled. The local word line selectors 102 are driven by the select lines from the global word line driver 80. The local bit lines 100 are driven by local bit line selectors 104 to which exemplary local bit line 100 is shown coupled.

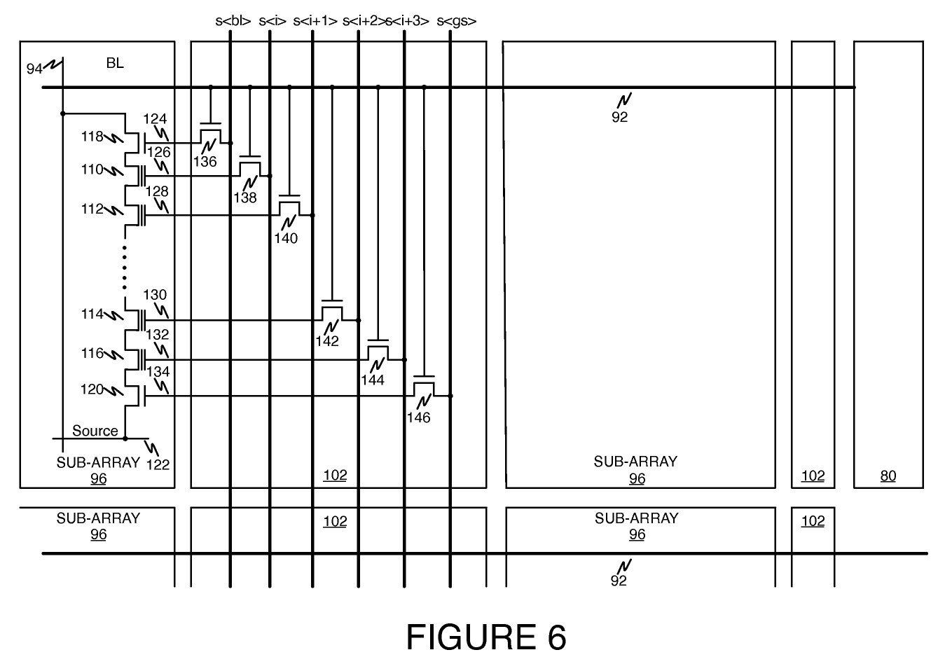

Referring now to FIG. 6, the operation of a typical local word line driver 92 is shown in more detail. An exemplary NAND string is shown including memory cell transistors 110, 112, 114, and 116. Select transistor 118 couples the string to a bit line 94. Another select transistor 120 couples the string to a source line 122.

The gates of memory cell transistors 110, 112, 114, and 116 and select transistors 118 and 120 are, respectively, coupled to word lines 124, 126, 128, 130, 132, and 134 through local selector transistors 136, 138, 140, 142, 144, and 146. The gates of local selector transistors 136, 138, 140, 142, 144, and 146 are coupled to a select line 92 common to the entire string. Select line 92 is driven by a global word line driver 80. The selector transistors 136, 138, 140, 142, 144, and 146 charge up the word lines 124, 126, 128, 130, 132, and 134 by means of global supply lines s<i> as indicated at the top of FIG. 6 that are common to more than one sub array.

The selection time of the local word lines 96 and local bit lines 98 is extremely faster than in a conventional NAND array. If “n” is the number of local bit-lines or local word-lines, the RC time-constant of the local connection is n² times smaller than the one of the global connections. For instance, the word lines and the bit lines are split into four local sub connections as shown in FIG. 5, the selection time of a cell becomes 16 times faster than if global word lines and bit lines were employed as in a conventional memory array. Instead of a memory cell-selection time of a few microseconds as in a conventional NAND array, the memory-cell selection time becomes tenths of nanoseconds in the sub-array architecture of the present invention.

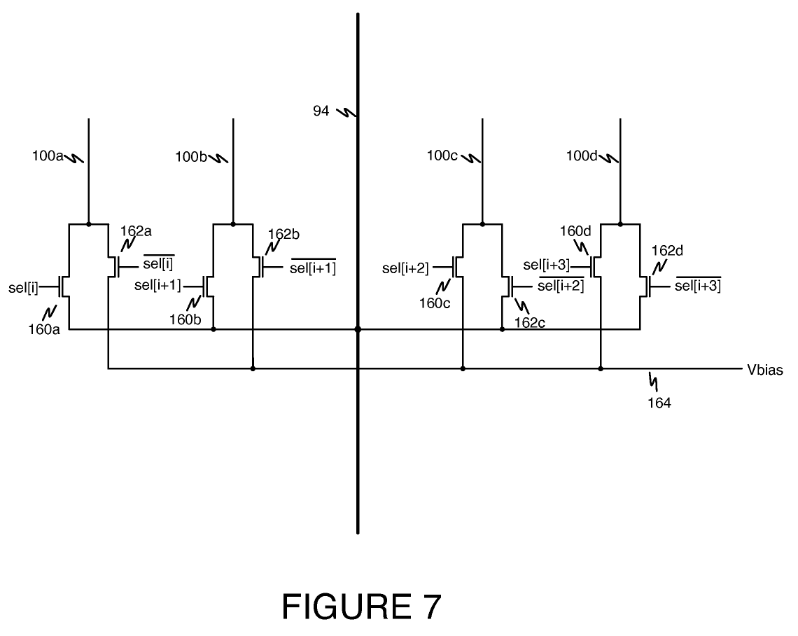

Referring now to FIG. 7, a schematic diagram shows how a hierarchical column decoder (inside of a local bit-line driver 102 in FIG. 5) can be used to address a NAND flash memory in accordance with the present invention. A multiplicity of selector transistors 160a through 160d selectively connect a group of local bit lines 100a through 100d , respectively, to a global bit line 94 by means of a set of selector signals sel<i>.

It should be noted that unselected ones of local bit lines 100a through 100d cannot be left floating, since, as known in the art, the program operation of a NAND memory implies the control of the unselected strings to prevent an unwanted programming of the cells that share the word line of the cell that is supposed to be programmed. In order to inhibit the program operation, the bit lines of the unselected strings are biased at a proper voltage (e.g. V_{CC}) to prevent the formation of the electric field necessary to the program operation. A hierarchical column decoder for a NAND memory according to the present invention also includes a set of selector transistors 162a through 162d that connect the unselected bit lines to a bias supply line 164 by the use of complementary selection signals designated by sel<i> with an overlying bar to indicate signal inversion. The bias supply line 164 biases the unselected bit-lines during any operation that cannot leave the bit lines left floating.

The additional area required due to the sub-array architecture is not significant compared to the great advantage of area given by the NAND memory cell versus the NOR memory. Global word lines and global bit lines are drawn with a pitch more relaxed then the local ones, then the RC time-constant related to their selection does not impact the overall performance. Moreover, by placing the sense amplifiers at the center of the array, the length of the bit lines connection is reduced.

The above illustrated architecture improves the performance of traditional NAND memory with a small drawback in terms of additional die area. Since the area of a NAND cell is about 60% of a NOR cell (6 F² vs 10 F²), the area efficiency is really improved with respect to a traditional NOR memory, obtaining the same read access performance.

While embodiments and applications of this invention have been shown and described, it would be apparent to those skilled in the art that many more modifications than mentioned above are possible without departing from the inventive concepts herein. The invention, therefore, is not to be restricted except in the spirit of the appended claims.

1. A flash memory integrated circuit including:
a plurality of flash memory arrays;
a global word line driver associated with each flash memory array, each global word line driver coupled to a plurality of select lines;
a plurality of sense amplifiers coupled to a plurality of bit lines;
a plurality of sub arrays in each flash memory array, each sub-array including a plurality of NAND flash memory cells coupled to local word lines and local bit lines;
a local word line driver associated with each and only one sub-array and coupled to the plurality of select lines and configured to drive the local word lines in its sub array associated with a selected plurality of NAND flash memory cells in its sub-array; and
a local bit line driver associated with each and only one sub-array and coupled between a selected plurality of local bit lines in each sub array and a selected plurality of bit lines.

2. The flash memory integrated circuit of claim 1 wherein the local word line driver associated with each sub-array and coupled to the plurality of select lines is configured to drive the local word lines in its sub array associated with the plurality of NAND flash memory cells in the same row of its sub-array.

3. The flash memory integrated circuit of claim 1 wherein the plurality of sub-arrays are arranged in rows and columns, a first sub-array disposed in a first row and a first column, a second sub-array disposed in the first row and a second column, a third sub-array disposed in the second row and the first column, and a fourth sub-array disposed in the second row and the second column.

4. The flash memory integrated circuit of claim 3 wherein a first group of the sense amplifiers are disposed between the first and third sub-arrays and a second group of the sense amplifiers are disposed between the second and fourth sub-arrays.

5. The flash memory integrated circuit of claim 1 wherein the plurality of sense amplifiers is divided into more than one group and each group of sense amplifiers is associated with at least one sub-array.

6. The array of claim 1 wherein unselected local bit lines are biased at a selected voltage.

7. The array of claim 6 wherein unselected local bit lines are biased at a voltage of about V_{CC}.

8. The flash memory of claim 1, wherein if “n” is the number of local bit-lines or local word-lines, the RC time-constant of a local connection to a sub-group is “n²” times smaller than that of a global connection.

9. The flash memory of claim 1, wherein when the word lines and the bit lines are split into four local sub-connections, then a selection time of a cell is 16 times faster compared to employing global word lines and global bit lines.

10. A flash memory integrated circuit including:
a plurality of flash memory arrays including a plurality of sub-arrays, each sub-array including a plurality of NAND flash memory cells coupled to local word lines and local bit lines;
a global word line driver associated with each flash memory array, each global word line driver coupled to a plurality of select lines;
a plurality of sense amplifiers coupled to a plurality of bit lines, each sense amplifier associated with a pair of adjacent memory arrays and drives bit lines in the pair of adjacent memory arrays; and
a local word line driver associated with each and only one sub-array and coupled to the plurality of select lines and to drive the local word lines associated with the NAND flash memory cells selected in each sub array; and
a local bit line driver associated with each and only one sub-array and coupled between selected local bit lines in each sub array and selected ones of the plurality of bit lines.

11. The flash memory integrated circuit of claim 10 wherein the local word line driver associated with each sub-array and coupled to the plurality of select lines is configured to drive the local word lines in its sub array associated with a plurality of NAND flash memory cells in the same row of its sub-array.

12. The flash memory integrated circuit of claim 10 wherein the plurality of sub-arrays are arranged in rows and columns, a first sub-array disposed in a first row and a first column, a second sub-array disposed in the first row and a second column, a third sub-array disposed in the second row and the first column, and a fourth sub-array disposed in the second row and the second column.

13. The flash memory integrated circuit of claim 12 wherein a first group of the sense amplifiers are disposed between the first and third sub-arrays and a second group of the sense amplifiers are disposed between the second and fourth sub-arrays.

14. The flash memory integrated circuit of claim 10 wherein the plurality of sense amplifiers is divided into more than one group and each group of sense amplifiers is associated with at least one sub-array.

15. The array of claim 10 wherein unselected local bit lines are biased at a selected voltage.

16. The array of claim 15 wherein unselected local bit lines are biased at a voltage of about V_{CC}.

17. The flash memory of claim 10, wherein if “n” is the number of local bit-lines or local word-lines, the RC time-constant of a local connection to a sub-group is “n²” times smaller than that of a global connection.

18. The flash memory of claim 10, wherein when the word lines and the bit lines are split into four local sub-connections, then a selection time of a cell is 16 times faster compared to employing global word lines and global bit lines.
